(19) United States
(12) Patent Application Publication
(10) Pub. No.: US 2007/0284137 A1
(43) Pub. Date: Dec. 13, 2007

(54) Method of Manufacturing Printed Circuit Board Base Sheet, Method of Manufacturing Printed Circuit Board, and Printed Circuit Board

(75) Inventors: Kyouyuu JO, Osaka (JP); Yasufumi MIYAKE, Osaka (JP)

Correspondence Address: AKIN GUMP STRAUSS HAUER & FELD L.L.P., ONE COMMERCE SQUARE, 2005 MARKET STREET, SUITE 2200, PHILADELPHIA, PA, 19103, US

(73) Assignee: NITTO DENKO CORPORATION, Osaka (JP)

(21) Appl. No.: 11/755,929

(22) Filed: May 31, 2007

(30) Foreign Application Priority Data
Jun. 7, 2006 (JP) 2006-158643

(51) Int. Cl. B32B 37/06; H05K 1/03

(52) U.S. Cl. 174/257; 156/322

(57) ABSTRACT

A printed circuit board base sheet is manufactured by laminating an insulating resin film and a metal foil using a laminate roller. A rustproofing layer containing chromium is formed on a surface of the metal foil. The temperature of the laminate roller is set to 330 to 390° C. A time period during which the metal foil and the laminate roller are brought into contact with each other immediately before a contact time point between the insulating resin film and the metal foil is set to 0.5 to 4.0 seconds.

### BACKGROUND OF THE INVENTION

1. Field of the Invention

The present invention relates to a method of manufacturing a printed circuit board base sheet, a method of manufacturing a printed circuit board, and a printed circuit board.

2. Description of the Background Art

In recent years, electronic equipment such as digital appliances and cellular phones has become increasingly sophisticated. With the sophistication, the wiring densities of printed circuit boards on which electronic components are to be mounted have increased. Therefore, an important subject is to improve the reliabilities of the electronic components.

Conventionally, ACFs (Anisotropic Conductive Films) have been used for adhesion between terminals of the electronic components and terminals of the printed circuit boards. In order to improve the reliabilities of the electronic components, it is necessary to improve the adhesive strengths of the ACFs.

Therefore, in a plasma treatment apparatus and a plasma treating method disclosed in JP2005-136086A, for example, when an IC (Integrated Circuit) is jointed to a polyimide film substrate, an oxygen plasma is irradiated onto a polyimide film before the joining. The publication describes that this causes a surface of the substrate to be activated, thereby causing joint strength between the polyimide film and an ACF to be improved.

In the method disclosed in JP2005-136086 A, however, the substrate and the electronic component must be subjected to contact bonding in a short time after the irradiation of plasma. Therefore, strict process management is required, resulting in reduced working efficiency. Further, a configuration for performing plasma treatment is required, resulting in increased manufacturing cost.

### SUMMARY OF THE INVENTION

An object of the present invention is to provide a method of manufacturing a printed circuit board base sheet in which joint strength between an electronic component and a printed circuit board can be improved, a method of manufacturing a printed circuit board, and a printed circuit board.

(1) According to an aspect of the present invention, a method of manufacturing a printed circuit board base sheet having a laminated structure of an insulating film and a metal foil, includes the step of laminating the insulating film and a metal foil having a chromium containing layer on its surface by passing them between first and second rollers in close proximity to each other. In the laminating step, the temperature of the first and second rollers is not less than 330° C., and the metal foil and the first roller are brought into contact with each other for not less than 0.5 seconds immediately before a time point at which the insulating film and the metal foil are brought into contact with each other.

In the method of manufacturing the printed circuit board base sheet, the insulating film and the metal foil are laminated by the first and second rollers. The temperature of the first and second rollers is not less than 330° C., and the metal foil and the first roller are brought into contact with each other for not less than 0.5 seconds before the insulating film and the metal foil are brought into contact with each other. In this case, when the insulating film and the metal foil are laminated, chromium in the chromium containing layer on the surface of the metal foil can be prevented from being transferred to the insulating film. That is, the content of chromium on a surface of the insulating film can be reduced.

The printed circuit board base sheet manufactured in such a way is changed into a printed circuit board by being further processed. Specifically, the metal foil is processed into a predetermined pattern, so that a wiring pattern is formed on the insulating film.

Here, in the printed circuit board base sheet manufactured by the manufacturing method, the content of chromium on the surface of the insulating film exposed by processing the metal foil is low, as described above.

In this case, when the printed circuit board base sheet and an electronic component are made to adhere to each other using an adhesive sheet such as an ACF (Anisotropic Conductive Film), joint strength between the surface of the insulating film exposed by processing the metal foil and the ACF can be improved.

This allows joint strength between the printed circuit board and the electronic component to be improved. As a result, even when electronic equipment is employed under a high-temperature and high-humidity environment for a long time, a joint portion between the printed circuit board and the electronic component can be prevented from being degraded, which can prevent the electronic equipment from failing.

(2) The temperature of the first and second rollers may be not more than 390° C. In this case, when the printed circuit board base sheet is manufactured, chromium in the chromium containing layer on the surface of the metal foil can be reliably prevented from being transferred to the insulating film. Consequently, the content of chromium on the surface of the insulating film can be sufficiently reduced.

(3) A time period during which the metal foil and the first roller are brought into contact with each other immediately before the time point at which the insulating film and the metal foil are brought into contact with each other may be not more than 4.0 seconds. In this case, when the printed circuit board base sheet is manufactured, chromium in the chromium containing layer on the surface of the metal foil can be reliably prevented from being transferred to the insulating film. Consequently, the content of chromium on the surface of the insulating film can be sufficiently reduced.

(4) The chromium containing layer may include first, second and third layers laminated in this order on the metal foil, the first layer may include nickel, molybdenum and cobalt, the second layer may be a chromate treatment layer, and the third layer may be a silane coupling agent treatment layer.

In this case, the chromium containing layer functions as a rustproofing layer, which can prevent the metal foil from corroding. This allows the reliability of the printed circuit board base sheet to be improved.

(5) A method of manufacturing a printed circuit board according to another aspect of the present invention comprises the steps of laminating an insulating film and a metal foil having a chromium containing layer on its surface by passing them between first and second rollers in close proximity to each other, and processing the metal foil into a predetermined pattern. In the step of laminating the insulating layer and the metal foil, the temperature of the first and second rollers is not less than 330° C., and the metal foil and the first roller are brought into contact with each other for not less than 0.5 seconds immediately before a time point at which the insulating film and the metal foil are brought into contact with each other.

In the method of manufacturing the printed circuit board, the insulating film and the metal foil are laminated by the first and second rollers. Thereafter, the metal foil is processed into the predetermined pattern. The temperature of the first and second rollers is not less than 330° C., and the metal foil and the first roller are brought into contact with each other for not less than 0.5 seconds immediately before the insulating film and the metal foil are brought into contact with each other.

In the manufacturing method, in the step of laminating the insulating film and the metal foil, chromium in the chromium containing layer on the surface of the metal foil can be prevented from being transferred to the insulating film. That is, the content of chromium on a surface of the insulating film can be reduced.

In this case, when the printed circuit board and an electronic component are made to adhere to each other using an adhesive sheet such as an ACF, joint strength between the surface of the insulating film exposed by processing the metal foil and the ACF can be improved.

This allows joint strength between the printed circuit board and the electronic component to be improved. As a result, even when electronic equipment is employed under a high-temperature and high-humidity environment for a long time, a joint portion between the printed circuit board and the electronic component can be prevented from being degraded, which can prevent the electronic equipment from failing.

(6) The temperature of the first and second rollers may be not more than 390° C. In this case, in the step of laminating the insulating film and the metal foil, chromium in the chromium containing layer on the surface of the metal foil can be reliably prevented from being transferred to the insulating film. Consequently, the content of chromium on the surface of the insulating film can he sufficiently reduced.

(7) A time period during which the metal foil and the first roller are brought into contact with each other immediately before the time point at which the insulating film and the metal foil are brought into contact with each other may be not more than 4.0 seconds. In this case, in the step of laminating the insulating film and the metal foil, chromium in the chromium containing layer on the surface of the metal foil can be reliably prevented from being transferred to the insulating film. Consequently, the content of chromium on the surface of the insulating film can be sufficiently reduced.

(8) The chromium containing layer may include first, second and third layers laminated in this order on the metal foil, the first layer may include nickel, molybdenum and cobalt, the second layer may be a chromate treatment layer, and the third layer may be a silane coupling agent treatment layer.

In this case, the chromium containing layer functions as a rustproofing layer, which can prevent the metal foil from corroding. This allows the reliability of the printed circuit board to be improved.

(9) A printed circuit board according to still another aspect of the present invention is a printed circuit board in which a wiring pattern is provided on an insulating film, the wiring pattern is formed by laminating the insulating film and a metal foil having a chromium containing layer on its surface by passing them between first and second rollers in close proximity to each other, and then processing the metal foil into a predetermined pattern, the temperatures of the first and second rollers is not less than 330° C., and the metal foil and the first roller are brought into contact with each other for not less than 0.5 seconds immediately before a time point at which the insulating film and the metal foil are brought into contact with each other.

The printed circuit board is manufactured by laminating the insulating film and the metal foil by the first and second rollers and then processing the metal foil into the predetermined pattern. The temperature of the first and second rollers is not less than 330° C., and the metal foil and the first roller are brought into contact with each other for not less than 0.5 seconds before the insulating film and the metal foil are brought into contact with each other.

In the printed circuit board, when the insulating film and the metal foil are laminated, chromium in the chromium containing layer on the surface of the metal foil can be prevented from being transferred to the insulating film. Consequently, the content of chromium on a surface of the insulating film is low.

In this case, when the printed circuit board and an electronic component are made to adhere to each other using an adhesive sheet such as an ACF, joint strength between the surface of the insulating film exposed by processing the metal foil and the ACF can be improved.

This allows joint strength between the printed circuit board and the electronic component to be improved. As a result, even when electronic equipment is employed under a high-temperature and high-humidity environment for a long time, a joint portion between the printed circuit board and the electronic component can be prevented from being degraded, which can prevent the electronic equipment from failing.

(10) The content of chromium on a surface of the insulating film exposed by processing the metal foil may be not more than 1.5 atom %.

In this case, when the printed circuit board and an electronic component are made to adhere to each other using an adhesive sheet such as an ACF, joint strength between the surface of the insulating film exposed by processing the metal foil and the ACF can be improved.

This allows joint strength between the printed circuit board and the electronic component to be sufficiently improved. As a result, even when electronic equipment is employed under a high-temperature and high-humidity environment for a long time, a joint portion between the printed circuit board and the electronic component can be prevented from being degraded, which can prevent the electronic equipment from failing.

Other features, elements, characteristics, and advantages of the present invention will become more apparent from the following description of preferred embodiments of the present invention with reference to the attached drawings.

### BRIEF DESCRIPTION OF THE DRAWINGS

FIG. 1 is a diagram for explaining a method of manufacturing a printed circuit board base sheet;

FIG. 2 is a schematic sectional view of the steps of an example of a method of manufacturing a printed circuit board by a subtractive method;

FIG. 3 is a schematic sectional view of the steps of an example of a method of manufacturing a printed circuit board by a subtractive method; and

FIG. 4 is a diagram for explaining a method of measuring peel strength.

### DESCRIPTION OF THE PREFERRED EMBODIMENTS

A printed circuit board base sheet and a printed circuit board according to an embodiment of the present invention will be described using the drawings.

(1) Printed Circuit Board Base Sheet

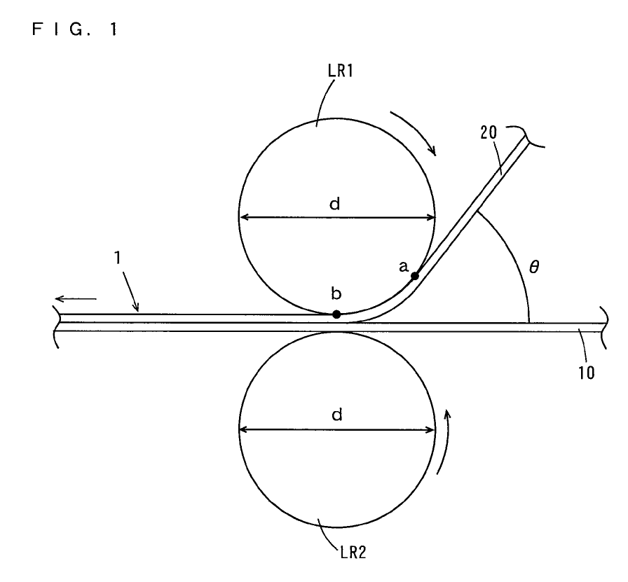

First, a method of manufacturing a printed circuit board base sheet will be described. FIG. 1 is a diagram for explaining a method of manufacturing a printed circuit board base sheet.

As shown in FIG. 1, a printed circuit board base sheet 1 is manufactured by laminating an insulating resin film 10 and a metal foil 20 using laminate rollers LR1 and LR2.

Examples of the insulating resin film 10 include one in which a thermoplastic polyimide layer is formed as an adhesive layer on a surface of a thermosetting polyimide film. The thickness of the thermosetting polyimide film is preferably 9 to 50 μm, and the thickness of the thermoplastic polyimide layer is preferably 1 to 3 μm. Usable as a material for the insulating resin film 10 are other materials such as polyethylene terephthalate, polyether nitrile, and polyether sulphone.

Examples of the metal foil 20 include a copper foil, an aluminum foil, and a nichrome foil. Further, a rustproofing layer containing chromium is formed on a surface of the metal foil 20. The rustproofing layer has a configuration in which a ternary alloy coating layer composed of nickel, molybdenum and cobalt, a chromate treatment layer, and a silane coupling agent treatment layer are laminated in this order on the metal foil 20, for example.

The thickness of the ternary alloy coating layer is preferably 0.001 to 0.03 μm. In the ternary alloy coating layer, the content of nickel is preferably 0.3 to 12 μg/cm², the content of molybdenum is preferably 0.3 to 10 μg/cm², and the content of cobalt is preferably 0.3 to 10 μg/cm². Further, the content of chromium in the rustproofing layer is 0.1 to 0.9 μg/cm², for example.

The diameter of the laminate rollers LR1 and LR2 is 380 mm, for example, and the rotational speed thereof is 0.5 to 2.3 m/min. Further, the temperature of the laminate rollers LR1 and LR2 is preferably not less than the glass transition temperature of the thermoplastic polyimide layer, for example, preferably not less than 330° C., and more preferably 330 to 390° C. The glass transition temperature of the thermoplastic polyimide layer is 235 to 300° C.

It is preferable that an angle θ (FIG. 1) between the insulating resin film 10 and the metal foil 20 that have not been laminated yet is 1.3 to 17.0° C. Although the metal foil 20 is brought into contact with an outer peripheral surface of the laminate roller LR1 at a position a, and the insulating resin film 10 and the metal foil 20 are laminated at a position b, as shown in FIG. 1, a time period required for the metal foil 20 to move from the position a to the position b is preferably not less than 0.5 seconds, and more preferably 0.5 to 4.0 seconds.

(2) Printed Circuit Board

A method of manufacturing a printed circuit board will be now described. The printed circuit board is manufactured using a subtractive method, an additive method, or a semi-additive method, for example. A method of manufacturing the printed circuit board using the subtractive method as an example will be now described using the drawings.

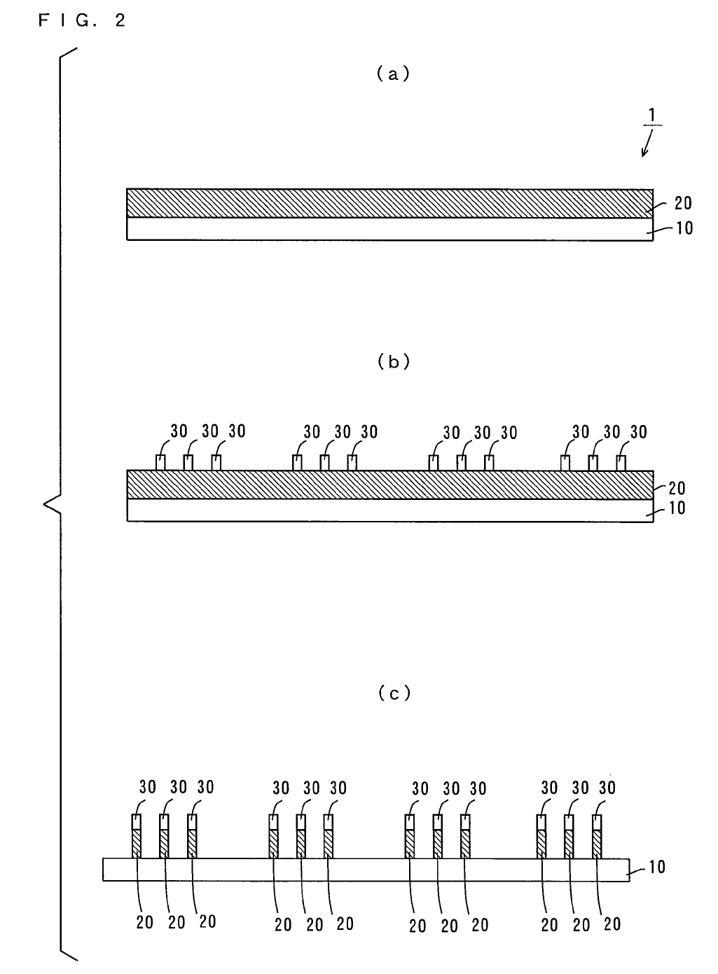

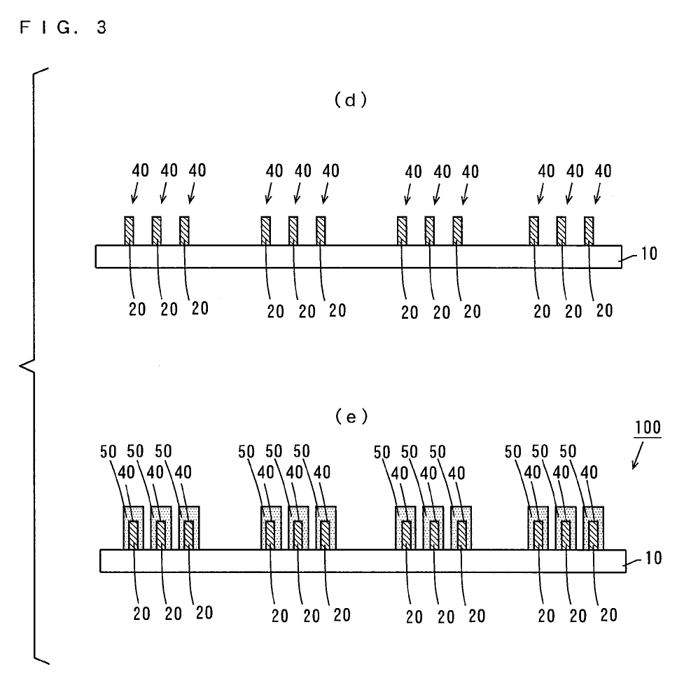

FIGS. 2 and 3 are schematic sectional views showing the steps of an example of the method of manufacturing the printed circuit board using the subtractive method.

As shown in FIG. 2(a), a printed circuit board base sheet 1 manufactured by the method described in FIG. 1 is first prepared.

Then, as shown in FIG. 2(b), etching resists 30 having a predetermined pattern are formed on a metal foil 20. The etching resists 30 are formed by forming a resist film on the metal foil 20 using a dry film resist or the like and exposing the resist film in a predetermined pattern, followed by development, for example.

Then, as shown in FIG. 2(c), an area of the metal foil 20, excluding respective areas below the etching resists 30, is removed by etching. Then, as shown in FIG. 3(d), the etching resists 30 are removed by a stripping liquid (peeling liquid). This causes wiring patterns 40 composed of the metal foil 20 to be formed.

Then, as shown in FIG. 3(e), electrolytic gold plating layers 50 are respectively formed so as to cover the wiring patterns 40. This causes a printed circuit board 100 to be completed.

Although description was made of a case where the wiring patterns 40 are formed on an upper surface of the printed circuit board base sheet 1, metal foils 20 may be respectively laminated on both surfaces of the insulating resin film 10, to form wiring patterns 40 on both surfaces of the printed circuit board base sheet 1.

(3) Effects

As described in the foregoing, in the present embodiment, the temperature of the laminate rollers LR1 and LR2 is set to not less than the glass transition temperature (330 to 390° C.) of the thermoplastic polyimide layer, to bring the metal foil 20 into contact with the laminate roller LR1 for 0.5 to 4.0 seconds before the laminating. This can prevent chromium in the rustproofing layer formed on the surface of the metal foil 20 from being transferred to the insulating resin film 10. As a result, the content of chromium can be set to not more than 1.5 atom % on the surface of the insulating resin film 10 exposed by forming the wiring patterns 40.

In this case, when an electronic component adheres on the printed circuit board 100 through an ACF, joint strength between the printed circuit board 100 and the ACF can be improved. This allows joint strength between the printed circuit board 100 and the electronic component to be improved. As a result, even when electronic equipment is employed under a high-temperature and high-humidity environment for a long time, a joint portion between the printed circuit board 100 and the electronic component can be prevented from being degraded, which can prevent the electronic equipment from failing.

(4) Correspondences Between Elements in the Claims and Parts in the Embodiments

In the following two paragraphs, non-limiting examples of correspondences between various elements recited in the claims below and those described above with respect to various preferred embodiments of the present invention are explained.

In the embodiment described above, the insulating resin film 10 is an example of an insulating film, the rustproofing layer is an example of a chromium containing layer, the laminate roller LR1 is an example of a first roller, the laminate roller LR2 is an example of a second roller, and the ternary alloy coating layer is an example of a first layer.

As each of various elements recited in the claims, various other elements having configurations or functions described in the claims can be also used.

### INVENTIVE EXAMPLES

Printed circuit boards 100 in inventive examples and comparative examples are produced, to evaluate joint strength between each of the printed circuit boards 100 and an ACF. Used as the insulating resin film 10 was an insulating resin sheet with an adhesive layer (trade name: PIXEO HC142, film thickness: 25 μm) manufactured by KANEKA CORPORATION, and used as the metal foil 20 was a copper foil (trade name: USLPSE, film thickness: 12 μm) manufactured by Nippon Denkai, Ltd.

### INVENTIVE EXAMPLES

In the inventive example 1, the temperature of the laminate rollers LR1 and LR2 was set to 340.0° C., the rotational speed was set to 2.0 m/min, an angle θ (see FIG. 1) between the insulating resin film 10 and the metal foil 20 that have not been laminated yet was set to 7.99 degrees, the contact length between the metal foil 20 and the laminate roller LR1 (the length from the position a to the position b on the outer periphery of the laminate roller LR1 in FIG. 1) before the laminating was set to 26.50 mm, and a contact time period during which the metal foil 20 and the laminate roller LR1 before the laminating are brought into contact with each other (a time period required for the metal foil 20 to move from the position a to the position b in FIG. 1) was set to 0.80 seconds.

In the inventive example 2, the temperature of the laminate rollers LR1 and LR2 was set to 365.0° C., the rotational speed was set to 2.0 m/min, the angle θ was set to 7.99 degrees, the contact length was set to 26.50 mm, and the contact time period was set to 0.80 seconds by the same method.

In the inventive example 3, the temperature of the laminate rollers LR1 and LR2 was set to 385.0° C., the rotational speed was set to 2.0 m/min, the angle θ was set to 7.99 degrees, the contact length was set to 26.50 mm, and the contact time period was set to 0.80 seconds by the same method.

In the inventive example 4, the temperature of the laminate rollers LR1 and LR2 was set to 365.0° C., the rotational speed was set to 1.0 m/min, the angle θ was set to 7.99 degrees, the contact length was set to 26.50 mm, and the contact time period was set to 1.59 seconds by the same method.

In the inventive example 5, the temperature of the laminate rollers LR1 and LR2 was set to 365.0° C., the rotational speed was set to 0.5 m/min, the angle θ was set to 7.99 degrees, the contact length was set to 26.50 mm, and the contact time period was set to 3.18 seconds by the same method.

The width of the wiring patterns 40 in a terminal portion of the printed circuit board 100 was 50 μm, and the distance between the wiring patterns 40 was 50 μm.

### COMPARATIVE EXAMPLE

In the comparative example 1, the temperature of the laminate rollers LR1 and LR2 was set to 365.0° C., the rotational speed was set to 2.5 m/min, the angle θ was set to 1.36 degrees, the contact length was set to 4.51 mm, and the contact time period was set to 0.11 seconds by the same method.

In the comparative example 2, the temperature of the laminate rollers LR1 and LR2 was set to 320.0° C., the rotational speed was set to 2.0 m/min, the angle θ was set to 1.36 degrees, the contact length was set to 4.51 mm, and the contact time period was set to 0.14 seconds by the same method.

In the comparative example 3, the temperature of the laminate rollers LR1 and LR2 was set to 320.0° C., the rotational speed was set to 2.0 m/min, the angle θ was set to 7.99 degrees, the contact length was set to 26.50 mm, and the contact time period was set to 0.80 seconds by the same method.

Table 1 shows the manufacturing conditions of the printed circuit boards 100 in the inventive examples and the comparative examples.

TABLE 1

| | | Rotational | | Contact | |
|---|---|---|---|---|---|
| | Temperature | Speed | Angle θ | Length | Time |
| | [° C.] | [m/min] | [°] | [mm] | [sec] |
| Inventive | 340.0 | 2.0 | 7.99 | 26.50 | 0.80 |
| Example 1 | | | | | |
| Inventive | 365.0 | 2.0 | 7.99 | 26.50 | 0.80 |
| Example 2 | | | | | |
| Inventive | 385.0 | 2.0 | 7.99 | 26.50 | 0.80 |
| Example 3 | | | | | |
| Inventive | 365.0 | 1.0 | 7.99 | 26.50 | 1.59 |
| Example 4 | | | | | |
| Inventive | 365.0 | 0.5 | 7.99 | 26.50 | 3.18 |
| Example 5 | | | | | |
| Comparative | 365.0 | 2.5 | 1.36 | 4.51 | 0.11 |
| Example 1 | | | | | |
| Comparative | 320.0 | 2.0 | 1.36 | 4.51 | 0.14 |
| Example 2 | | | | | |
| Comparative | 320.0 | 2.0 | 7.99 | 26.50 | 0.80 |
| Example 3 | | | | | |

(Evaluation)

ESCA (Electron Spectroscopy for Chemical Analysis) analysis and joint strength measurement of the printed circuit boards 100 in the inventive examples and the comparative examples produced in the foregoing manner were made, to consider the results of the analysis and the results of the measurement.

(1) ESCA Analysis

First, the results of the ESCA analysis will be described. In the ESCA analysis, Quantum 2000 manufactured by ULVAC-PHI, Inc. was used.

In the ESCA analysis, C (carbon), N (nitrogen), O (oxygen), Si (silicon), P (phosphorus), S (sulfur), Cl (chlorine), Cr (chromium), Co (cobalt), Cu (copper), Br (bromine), and Mo (molybdenum) were detected.

The content of Cr in the total amount of the detected elements was 1.2 atom % in the inventive example 1, 0.2 atom % in the inventive example 2, 0.3 atom % in the inventive example 3, less than 0.1 atom % in the inventive example 4, less than 0.1 atom % in the inventive example 5, 2.6 atom % in the comparative example 1, 2.3 atom % in the comparative example 2, and 2.0 atom % in the comparative example 3.

(2) Joint Strength Measurement

Then, the joint strength measurement will be described. In the joint strength measurement, peel strength was measured in conformity with JIS-C6471.

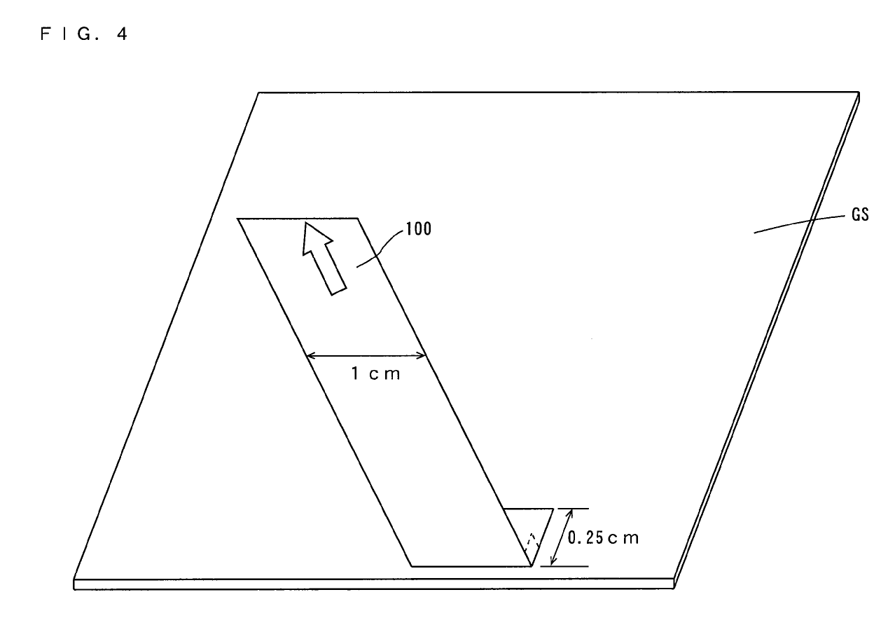

FIG. 4 is a diagram for explaining a method of measuring peel strength. As shown in FIG. 4, in the joint strength measurement, the printed circuit boards 100 in the inventive examples 1 to 5 and the comparative examples 1 to 3 were produced with a width of 1 cm, and a terminal portion (0.25 cm in length) of each of the printed circuit boards was made to adhere to a glass substrate GS by an ACF. The printed circuit board 100 that had adhered to the glass substrate GS was peeled off at a peeling speed of 50 mm/min in a direction perpendicular to the glass substrate GS, to measure the peel strength. An electrolytic gold plating layer was formed in the terminal portion of the printed circuit board 100 used in the joint strength measurement.

Furthermore, the peel strength was measured with respective to each of the printed circuit board 100 in a state where the temperature and humidity thereof were not changed after the adhesion (in an initial state), the printed circuit board 100 in a state where it was left for 24 hours within a 80° C. and 95% RH atmosphere after the adhesion, and the printed circuit board 100 in a state where it was left for 1000 hours within a 80° C. and 95% RH atmosphere after the adhesion.

As a result, the peel strength in the initial state was 10.2 N/cm, the peel strength after 24 hours was 8.7 N/cm, and the peel strength after 1000 hours was 8.7 N/cm in the inventive example 1.

Similarly, the peel strength in the initial state was 10.2 N/cm, the peel strength after 24 hours was 9.4 N/cm, and the peel strength after 1000 hours was 8.9 N/cm in the inventive example 2.

The peel strength in the initial state was 9.5 N/cm, the peel strength after 24 hours was 9.0 N/cm, and the peel strength after 1000 hours was 8.2 N/cm in the inventive example 3.

The peel strength in the initial state was 10.4 N/cm, the peel strength after 24 hours was 8.9 N/cm, and the peel strength after 1000 hours was 8.8 N/cm in the inventive example 4.

The peel strength in the initial state was 9.5 N/cm, the peel strength after 24 hours was 8.9 N/cm, and the peel strength after 1000 hours was 8.4 N/cm in the inventive example 5.

The peel strength in the initial state was 8.3 N/cm, the peel strength after 24 hours was 2.3 N/cm, and the peel strength after 1000 hours was 2.1 N/cm in the comparative example 1.

The peel strength in the initial state was 9.0 N/cm, the peel strength after 24 hours was 4.2 N/cm, and the peel strength after 1000 hours was 3.5 N/cm in the comparative example 2.

The peel strength in the initial state was 8.9 N/cm, the peel strength after 24 hours was 4.7 N/cm, and the peel strength after 1000 hours was 3.8 N/cm in the comparative example 3.

Table 2 shows the results of the ESCA analysis (the content of Cr) and the results of the measurement of the joint strength (peel strength).

TABLE 2

| | | Peel Strength [N/cm] | | |
|---|---|---|---|---|
| | Cr content | Initial | 80° C., 95% RH | 80° C., 95% RH |
| | [atom %] | State | After 24 h | After 1000 h |
| Inventive | 1.2 | 10.2 | 8.7 | 8.7 |
| Example 1 | | | | |
| Inventive | 0.2 | 10.2 | 9.4 | 8.9 |
| Example 2 | | | | |
| Inventive | 0.3 | 9.5 | 9.0 | 8.2 |
| Example 3 | | | | |
| Inventive | <0.1 | 10.4 | 8.9 | 8.8 |
| Example 4 | | | | |
| Inventive | <0.1 | 9.5 | 8.9 | 8.4 |
| Example 5 | | | | |
| Comparative | 2.6 | 8.3 | 2.3 | 2.1 |
| Example 1 | | | | |
| Comparative | 2.3 | 9.0 | 4.2 | 3.5 |
| Example 2 | | | | |
| Comparative | 2.0 | 8.9 | 4.7 | 3.8 |
| Example 3 | | | | |

(3) Consideration

As shown in Table 2, the respective peel strengths of the printed circuit boards 100 in the comparative examples 1 to 3 are lower than the respective peel strengths of the printed circuit boards in the inventive examples 1 to 5. Particularly, the respective peel strengths of the printed circuit hoard 100 that was left for 24 hours and 1000 hours at a 80° C. and 95% RH atmosphere are significantly reduced. Thus, it is conceivable that the respective joint strengths between the printed circuit boards 100 in the comparative examples 1 to 3 and the ACF are made significantly lower than the respective joint strengths between the printed circuit boards 100 in the inventive examples 1 to 5 and the ACF.

Here, as shown in Table 2, the respective contents of chromium (Cr) in an area to which a surface of the insulating resin film 10 is exposed in the comparative examples 1 to 3 are higher than those in the inventive examples 1 to 5. Thus, it is conceivable that the respective peel strengths of the printed circuit boards 100 in the comparative examples 1 to 3 are reduced.

In the comparative example 1, the increase in the content of chromium on the surface of the insulating resin film 10 is attributed to the fact that the time period during which the metal foil 20 and the laminate roller LR1 before the laminating are brought into contact with each other is shorter, as compared with those in the inventive examples 1 to 5, as shown in Table 1.

In the comparative example 2, the increase is attributed to the fact that the temperature of the laminate rollers LR1 and LR2 is lower and the time period during which the metal foil 20 and the laminate roller LR1 before the laminating are brought into contact with each other is shorter, as compared with those in the inventive examples 1 to 5.

In the comparative example 3, the increase is attributed to the fact that the temperature of the laminate rollers LR1 and LR2 is lower, as compared with those in the inventive examples 1 to 5.

Consequently, it is conceivable that chromium contained in the metal foil 20 can be prevented from being transferred to the insulating resin film 10 by setting the temperature of the laminate rollers LR1 and LR2 to a suitable temperature as well as sufficiently ensuring the time period during which the metal foil 20 and the laminate roller LR1 before the laminating are brought into contact with each other. Thus, it is conceivable that the content of chromium in the area to which the surface of the insulating resin film 10 is exposed can be reduced; consequently, the peel strength of the printed circuit board 100 can be improved. That is, the joint strength between the printed circuit board 100 and the ACF can be improved.

While preferred embodiments of the present invention have been described above, it is to be understood that variations and modifications will be apparent to those skilled in the art without departing the scope and spirit of the present invention. The scope of the present invention, therefore, is to be determined solely by the following claims.

What is claimed is:

1. A method of manufacturing a printed circuit board base sheet having a laminated structure of an insulating film and a metal foil, comprising the step of:
laminating said insulating film and a metal foil having a chromium containing layer on its surface by passing them between first and second rollers in close proximity to each other, in the laminating step, the temperature of said first and second rollers is not less than 330° C., and said metal foil and said first roller are brought into contact with each other for not less than 0.5 seconds immediately before a time point at which said insulating film and said metal foil are brought into contact with each other.

2. The method according to claim 1, wherein the temperature of said first and second rollers is not more than 390° C.

3. The method according to claim 1, wherein a time period during which said metal foil and said first roller are brought into contact with each other immediately before the time point at which said insulating film and said metal foil are brought into contact with each other is not more than 4.0 seconds.

4. The method according to claim 1, wherein said chromium containing layer includes first, second and third layers laminated in this order on said metal foil, said first layer includes nickel, molybdenum and cobalt, said second layer is a chromate treatment layer, and said third layer is a silane coupling agent treatment layer.

5. A method of manufacturing a printed circuit board, comprising the steps of:
laminating an insulating film and a metal foil having a chromium containing layer on its surface by passing them between first and second rollers in close proximity to each other, and
processing said metal foil into a predetermined pattern,
in the step of laminating said insulating layer and the metal foil, the temperature of said first and second rollers is not less than 330° C., and said metal foil and said first roller are brought into contact with each other for not less than 0.5 seconds immediately before a time point at which said insulating film and said metal foil are brought into contact with each other.

6. The method according to claim 5, wherein the temperature of said first and second rollers is not more than 390° C.

7. The method according to claim 5, wherein a time period during which said metal foil and said first roller are brought into contact with each other immediately before the time point at which said insulating film and said metal foil are brought into contact with each other is not more than 4.0 seconds.

8. The method according to claim 5, wherein
said chromium containing layer includes first, second and third layers laminated in this order on said metal foil,
said first layer includes nickel, molybdenum and cobalt,
said second layer is a chromate treatment layer, and
said third layer is a silane coupling agent treatment layer.

9. A printed circuit board wherein
a wiring pattern is provided on an insulating film,
said wiring pattern is formed by laminating said insulating film and a metal foil having a chromium containing layer on its surface by passing them between first and second rollers in close proximity to each other, and then processing said metal foil into a predetermined pattern,
the temperature of said first and second rollers is not less than 330° C., and
said metal foil and said first roller are brought into contact with each other for not less than 0.5 seconds immediately before a time point at which said insulating film and said metal foil are brought into contact with each other.

10. The printed circuit board according to claim 9, wherein the content of chromium on a surface of said insulating film exposed by processing said metal foil is not more than 1.5 atom %.
